(19) United States
(12) Patent Application Publication
(10) Pub. No.: US 2026/0074092 A1
(43) Pub. Date: Mar. 12, 2026

(54) Cable Unit for Connecting a Gradient Coil to a Power Amplifier

(71) Applicant: Siemens Healthineers AG, Forchheim (DE)

(72) Inventors: Thomas Beck, Dormitz (DE); Reinhard Kramer, Erlangen (DE)

(73) Assignee: Siemens Healthineers AG, Forchheim (DE)

(21) Appl. No.: 19/326,850

(22) Filed: Sep. 12, 2025

(30) Foreign Application Priority Data
Sep. 12, 2024 (DE) 10 2024 208 702.5

(51) Int. Cl. H01B 9/00; G01R 33/385; H01B 9/04; H01R 11/01

(52) U.S. Cl. CPC H01B 9/006; G01R 33/3852; H01B 9/04; H01R 11/01; H01R 2201/22

(57) ABSTRACT

A cable unit designed for connecting a gradient coil, which is embodied to generate a magnetic field gradient in one spatial direction, to a power amplifier, having at least one feed line, wherein the feed line comprises at least two cable elements at least in sections, and the at least two cable elements are connected electrically in parallel.

### TECHNICAL FIELD

The disclosure relates to a cable unit connecting a gradient coil to a power amplifier and to a system having a gradient coil unit, a gradient control unit, and three connection units comprising a cable unit of said type.

### BACKGROUND

Magnetic resonance imaging is based on alternating electromagnetic fields (RF fields) generated by a magnetic resonance device and their interaction with a static magnetic field of, most commonly, 1.5 tesla, 3 tesla, or 7 tesla. In addition, gradient pulses are played out with the aid of a gradient coil unit. Radiofrequency pulses, for example, excitation pulses, are then transmitted by means of suitable antenna equipment via a radiofrequency antenna unit, which leads to the nuclear spins of certain atoms being excited into resonance by said radiofrequency pulses and being tipped through a defined flip angle with respect to the magnetic field lines of the main magnetic field. During the relaxation of the nuclear spins, radiofrequency signals, also referred to as magnetic resonance signals, are emitted, received by means of suitable radiofrequency antennas, and then processed further. Finally, the desired image data can be reconstructed from the raw data acquired in the manner described.

The magnetic resonance device and more particularly the gradient coil unit required for spatial encoding in magnetic resonance imaging are typically controlled with the aid of a control unit and by means of power amplifiers, in particular controlled by means of a gradient control unit. The gradient coil unit comprises three gradient coils. The three gradient coils are designed to generate a magnetic field gradient in three different spatial directions that are typically orthogonal to one another. Conventionally, a gradient coil is connected to a power amplifier via a gradient cable. The gradient cable, hereinafter also referred to as a cable unit, may comprise a feed line and a return line and/or be embodied as a coaxial cable comprising a feed line and a return line in an integrated unit. The power amplifiers generate electric currents of up to 1500 A, in exceptional cases of up to 3000 A, at frequencies in the range between 100 Hz and 10 kHz. These electric currents are supplied to the gradient coil unit by means of the gradient cable.

The ohmic losses occurring in this process can lead to heat buildup in the gradient cable. The temperature rise during the operation of the gradient coil unit increases with the current intensity in the gradient cable. Conventional practice to reduce heat buildup involves the use of copper cables, for example, having a cross-sectional area of more than 50 mm² and an outer diameter of more than 40 mm. Furthermore, depending on constraints imposed by the building, the gradient cables can be cooled by means of ventilation. In addition, the gradient cables are typically exposed to mechanical vibrations.

### SUMMARY

The object underlying the disclosure is to disclose a particularly powerful and robust cable unit for connecting a gradient coil to a power amplifier. The object is achieved by means of the features of the independent claims. Advantageous aspects are described in the dependent claims.

The cable unit, according to the disclosure, is designed to connect a gradient coil, which is embodied for generating a magnetic field gradient in one spatial direction, to a power amplifier. For this purpose, the cable unit has at least one feed line, wherein the feed line comprises at least two cable elements at least in sections, wherein the at least two cable elements are electrically connected in parallel.

A cable element typically comprises an electrical conductor and an insulating surface surrounding the electrical conductor, in particular a protective sheath, for example made of plastic. The cable element is typically elongate in design. The electrical conductor can be embodied as a single conductor and/or as a single-wired or multi-wired combination of single lines. In the cross-section of the cable element, the electrical conductor is typically completed externally by the insulating surface, in particular, the protective sheath.

The feed line is designed to conduct an electric current from the energy source, in particular the power amplifier, to the load, in particular the gradient coil. The feed line is typically at least 2 m, preferably at least 4 m, particularly preferably at least 5 m in length. The feed line can, for example, lead through a filter unit and/or an RF shield. The feed line is designed according to the disclosure such that in at least one subarea, i.e., in sections, the feed line is subdivided into at least two cable elements. In this arrangement, the at least two cable elements are electrically connected parallel to one another, for example, by means of cable shoes. The at least two cable elements can also be physically arranged approximately parallel to one another. The feed line can also be designed such that it comprises a different number of cable elements electrically connected in parallel in different sections of the feed line. The feed line can be designed such that it comprises three or four or more than four cable elements electrically connected in parallel with one another within one section of the feed line. Over its total length, the feed line may comprise two or three or four or more than four cable elements electrically connected in parallel with one another.

The cable unit, according to the disclosure, enables the gradient coil to be driven at particularly high current intensities, such that particularly high magnetic field gradients having particularly fast rise and fall rates can be achieved. A multimembered guidance of cable elements furthermore allows a redundant and therefore robust configuration, as well as a better ventilation of the individual cable elements and consequently a more intensive cooling of the cable unit. The individual parallel-connected cable elements can have a smaller cross-section than a feed line comprising just one cable element at a constant maximum current intensity, such that the required conductive material is approximately consistent.

An aspect of the cable unit provides that at least one cable element of the two cable elements has a cross-sectional area of less than 45 mm², preferably of less than 38 mm², particularly preferably of less than 30 mm². The parallel circuit, according to the disclosure, consisting of at least two cable elements, allows a higher flow of current compared to the use of one cable element having the same cross-sectional area, such that the cross-sectional area of at least one cable element can be reduced in size. Preferably, all the cable elements of the feed line and/or of the cable unit have a cross-sectional area of less than 45 mm², preferably of less than 38 mm², particularly preferably of less than 30 mm². A smaller cross-sectional area allows a higher degree of flexibility and a smaller bending radius of the corresponding cable element, such that this aspect enables the cable elements to be configured in a flexible and individual arrangement. As a result, the installation of such a cable unit, which is typically located in a tight space and/or is routed in the floor, is made easier.

An aspect of the cable unit provides that the cable unit additionally comprises a return line having at least one cable element, which return line is electrically connected in series with the feed line. The return line is designed to conduct an electrical current from the power-consuming load, in particular the gradient coil, to the gradient control unit comprising the power amplifier. The return line can comprise one cable element. The return line can comprise at least two cable elements interconnected electrically in parallel at least in sections. The feed line, the gradient coil, and the return line are typically electrically connected in series. This aspect enables a robust power supply to be provided to the gradient coil.

An aspect of the cable unit provides that the feed line and the return line are designed jointly as at least two coaxial cables which are at least partially connected electrically in parallel. The feed line can be embodied, for example, as the inner conductor of a coaxial cable and the return line as the outer conductor of a coaxial cable, wherein the inner conductor and the outer conductor are separated from one another by an insulating layer. As a result, the inner conductor can be regarded as a cable element. The outer conductor is enclosed externally by a protective sheath such that the outer conductor also can be regarded as a cable element. A corresponding electrical parallel circuit composed of coaxial cables allows an integrated feed line and return line having higher current intensities and/or smaller cross-sectional areas of the cable elements than when a single coaxial cable is used as a feed line. Thus, pliable coaxial cables can also be used and employed in a flexible manner.

The disclosure further relates to a system comprising a gradient coil unit having three gradient coils, a gradient control unit having three power amplifiers, and three connection units, each connecting a gradient coil to a power amplifier and each having a feed line, wherein the three gradient coils are in each case designed to generate a magnetic field gradient in three different spatial directions, each feed line comprises at least one cable element in each case,

and a first connection unit of the three connection units is embodied as a cable unit according to the disclosure.

In order to avoid adversely affecting the functionality of a magnetic resonance device, the latter is typically located in a separate RF-shielded room, which is preferably enclosed by an RF shield which in particular is able to shield the generated fields from external influences and prevents the electromagnetic fields generated by the magnetic resonance device from spreading outside the RF-shielded room. The gradient coil unit, typically a component of a magnetic resonance device, is accordingly typically arranged inside the RF-shielded room. The magnetic resonance device and, in particular, the gradient coil unit required for spatial encoding in magnetic resonance imaging are typically controlled with the aid of a gradient control unit and by means of power amplifiers, which are arranged outside of the RF-shielded room. Accordingly, the three connection units are typically guided through an RF shield, for which purpose the RF shield may comprise a filter plate for maintaining the shielding properties. The system, according to the disclosure, can comprise the magnetic resonance system.

The system, as disclosed, comprises the components required to drive the gradient coil unit. The use of at least two cable elements for a feed line enables a gradient coil unit to be driven with particularly high magnetic field gradients and at particularly fast rise and fall rates.

Further aspects of the system, according to the disclosure, are designed analogously to the aspects of the cable unit according to the disclosure. The advantages of the system substantially correspond to the advantages of the cable unit according to the disclosure, which have been explained in detail in the foregoing. Features, advantages, or alternative aspects of the cable unit mentioned in this context, as well as the alternative aspects of the system, can equally be applied to the other claimed subject matters, and vice versa.

An aspect of the system provides that the first connection unit connects a first gradient coil of the three gradient coils to a first power amplifier of the three power amplifiers, and the first gradient coil is embodied for generating a magnetic field gradient in the x-direction or in the y-direction. A gradient coil unit is typically designed as a hollow cylinder around a longitudinal axis, wherein the longitudinal axis is arranged horizontally and is designated as the z-axis, i.e., is embodied in the z-direction. The x-direction typically designates a direction oriented orthogonally to the z-axis and likewise horizontally. The y-direction is embodied orthogonally to the x-axis and to the y-direction. Within the scope of the readout gradient, the x-direction is a typically particularly heavily loaded spatial direction of the magnetic field gradients used in the course of the MR imaging, with the result that typically, in the context of the driving of the first gradient coil, the first connection unit particularly frequently conducts particularly high electric currents and consequently, when a cable element is used in the conventional manner, is exposed to a particularly high increase in temperature. The use of a cable unit according to the disclosure for the first connection unit enables better temperature regulation as a result of lower loading of individual cable elements.

An aspect of the system provides that at least one cable element of the feed line of the first connection unit has a larger cross-sectional area than cable elements of the feed lines of a second connection unit and/or of a third connection unit of the three connection units. This aspect provides that, in addition to the electrical parallel connection consisting of at least two cable elements, the particularly heavily loaded first connection unit has a larger cross-sectional area than the other cable elements. It has been recognized that electrical conductors having a larger cross-sectional area heat up less than electrical conductors having a smaller cross-sectional area. This aspect accordingly provides a particularly robust and powerful feed line and electrical power supply to the first gradient coil.

An aspect of the system provides that a second connection unit of the three connection units is designed as a cable unit, as disclosed. According to this aspect, at least two gradient coils having a flexible and at the same time powerful connection unit can be supplied with electrical power.

An aspect of the system provides that each connection unit of the three connection units is designed as a cable unit according to the disclosure. Each of the three connection units accordingly comprises a feed line, each having, at least in sections, two cable elements electrically connected in parallel such that, according to this aspect, at least six cable elements are provided as feed lines for the gradient coil unit. The at least six cable elements are typically interconnected in parallel at least in pairs. The at least six cable elements are preferably not different in terms of cross-section, structure and/or type. The at least six cable elements are preferably mutually interchangeable, as a result of which the connection units are standardized and scalable. This enables the system to be implemented at a reasonable cost.

Furthermore, already installed conventional systems which connect a gradient coil unit to a gradient control unit via three feed lines, each comprising precisely one cable element, can be upgraded in such a way that each of the three feed lines is supplemented by a further cable element electrically connected in parallel to the existing cable element. This enables the gradient coil unit to be provided with an improved energy supply without the need for a complete rewiring.

An aspect of the system provides that the feed line of a third connection unit of the three connection units comprises one cable element and is free of cable elements electrically connected in parallel, the third connection unit accordingly being free from a cable unit according to the disclosure. This enables an individual cabling of the third gradient coil depending on its expected use and accordingly required power, as well as providing a configuration tailored to the asymmetric use of the gradient coil unit.

An aspect of the system provides that the third connection unit connects a third gradient coil of the three gradient coils to a third power amplifier of the three power amplifiers, and the third gradient coil is designed to generate a magnetic field gradient in the z-direction. In particular, given a conventional orientation of the image data to be generated by means of the magnetic resonance device, the magnetic field gradients in the z-direction require less power than the magnetic field gradients in the x-direction and/or in the y-direction. This aspect consequently allows an efficient use of the system.

An aspect of the system provides that the number of cable elements of the feed lines of at least two of the three connection units are different from one another. This aspect allows an efficient use of the system.

An aspect of the system provides that the cross-sections of the cable elements of the feed lines of at least two of the three connection units are different from one another. The cable elements for feed lines of more heavily loaded gradient coils can accordingly be chosen thicker than the feed lines for less heavily loaded gradient coils. This enables a uniform change in temperature in all the cable elements during operation of the gradient coil unit.

An aspect of the system provides that each connection unit of the three connection units in each case comprises a return line having at least one cable element which is electrically connected in series to the corresponding feed line. There are typically one feed line, one gradient coil and one return line electrically connected in series in each case such that the system comprises at least three electrical circuits. This allows the gradient coil unit to be supplied with electrical power in an individual and robust manner.

An aspect of the system provides that the system additionally comprises a terminal unit, which terminal unit is arranged at the surface of a housing enclosing the gradient coil unit and has three terminal elements, wherein all the cable elements or the cable element of a feed line in each case can be attached to a respective terminal element. The terminal unit preferably comprises three further terminal elements, wherein all the cable elements or the cable element of a return line in each case can be attached to a respective further terminal element. A terminal element typically enables a reversibly detachable attachment and/or connection of at least one cable element to a gradient coil. A terminal element is typically embodied as a cable shoe. A terminal element may also comprise a coaxial connector, in particular in a coaxial aspect of the feed line and return line. The system can comprise an analogous second terminal unit which provides a reversibly detachable attachment and/or connection of at least one cable element to a power amplifier. This aspect allows a simple exchange of cable elements and an efficient installation of the system.

### BRIEF DESCRIPTION OF THE DRAWINGS

Further advantages, features, and details of the disclosure will become apparent from the exemplary aspects described in the following, as well as with reference to the drawings, in which:

FIG. 1 shows a schematic view of a first aspect of a cable unit according to the disclosure,

FIG. 2 shows a schematic view of a second aspect of a cable unit according to the disclosure,

FIG. 3 shows a schematic view of a first aspect of a system according to the disclosure, and

FIG. 4 shows a schematic view of a second aspect of a system according to the disclosure.

### DETAILED DESCRIPTION

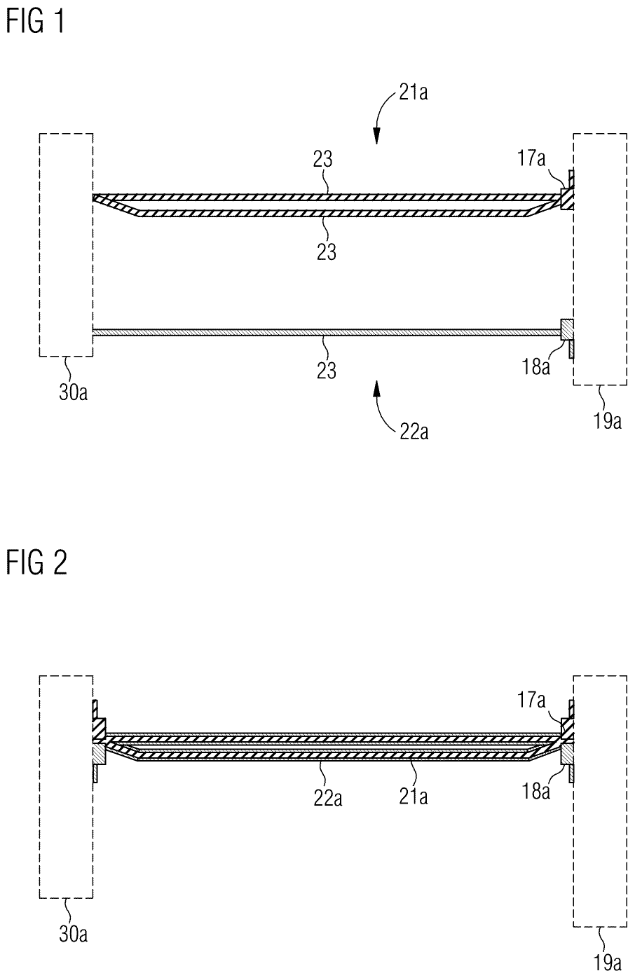

FIG. 1 shows a schematic view of a first aspect of a cable unit according to the disclosure. The cable unit connects a gradient coil 19a to a power amplifier 30a, wherein the gradient coil 19a and the power amplifier 30a are not included in the cable unit and are merely indicated in FIG. 1. The cable unit has a feed line 21a. The feed line 21a comprises two cable elements 23, wherein the two cable elements 23 are electrically connected in parallel. The two cable elements 23 of the feed line 21a have a cross-sectional area of less than 45 mm². The cable unit additionally comprises a return line 22a having a cable element 23, wherein the return line 22a is electrically connected in series to the feed line 21a and, in particular, leads from the gradient coil 19a to the power amplifier 30a, i.e., electrically connects the gradient coil 19a to the power amplifier 30a. In particular, the feed line 21a is connected in series to the return line 22a via the gradient coil 19a. In the aspect shown, the cable unit is further connected to the gradient coil 19a via a terminal element 17a and a further terminal element 18a. The terminal element 17a is arranged at the surface of the gradient coil 19a and enables an electrical connection between the feed line 21a and the gradient coil 19a. The further terminal element 18a is arranged at the surface of the gradient coil 19a and enables an electrical connection between the return line 22a and the gradient coil 19a.

FIG. 2 shows a schematic view of a second aspect of a cable unit according to the disclosure. The second aspect differs from the first aspect shown in FIG. 1 in that the feed line 21a and the return line 22a are embodied in an integrated unit as coaxial cables. In this case, the feed line 21a comprises two cable elements which are embodied as inner conductors of two coaxial cables electrically connected in parallel. The return line 22a is formed by the corresponding outer conductor of the two coaxial cables electrically connected in parallel.

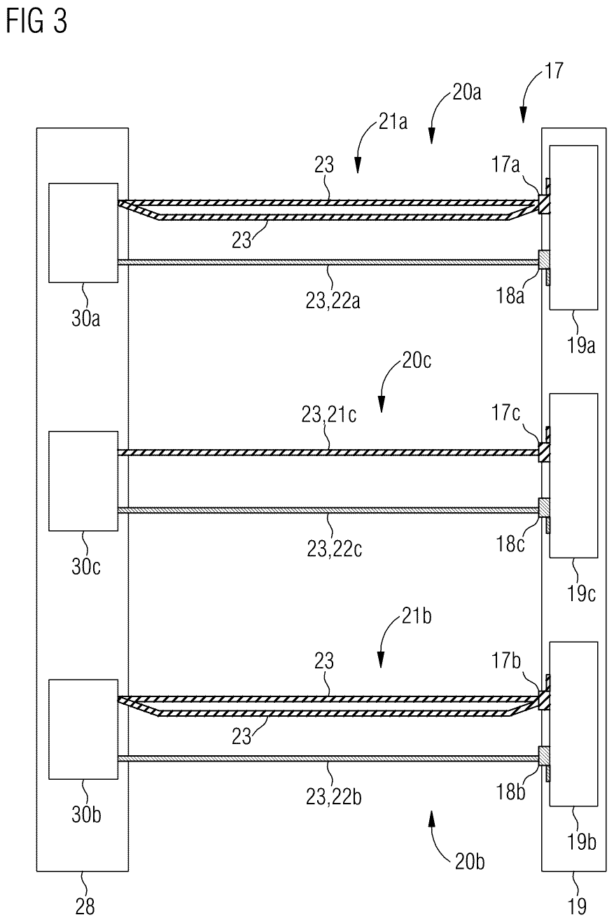

FIG. 3 shows a schematic view of a first aspect of a system according to the disclosure. The system comprises a gradient coil unit 19 having three gradient coils 19a, 19b, 19c, a gradient control unit 28 having three power amplifiers 30a, 30b, 30c, and three connection units 20a, 20b, 20c, each connecting a gradient coil 19a, 19b, 19c to a power amplifier 30a, 30b, 30c. The three connection units 20a, 20b, 20c each have a feed line 21a, 21b, 21c, each of which comprises at least one cable element 23. The three gradient coils 19a, 19b, 19c are each embodied for generating a magnetic field gradient in three different spatial directions. The first connection unit 20a and the second connection unit 20b of the three connection units 20a, 20b, 20c are embodied as cable units according to the disclosure.

The first connection unit 20a connects a first gradient coil 19a of the three gradient coils 19a, 19b, 19c to a first power amplifier 30a of the three power amplifiers 30a, 30b, 30c, and the first gradient coil 19a is embodied for generating a magnetic field gradient in the x-direction. The first connection unit 20a additionally comprises a first return line 22a, which has a cable element 23 that is electrically connected in series to the first feed line 21a. The first feed line 21a, the first gradient coil 19a, the first return line 22a, and the first power amplifier 30a typically form a closed electrical circuit.

The second connection unit 20b connects a second gradient coil 19b of the three gradient coils 19a, 19b, 19c to a second power amplifier 30b of the three power amplifiers 30a, 30b, 30c, and the second gradient coil 19a is embodied for generating a magnetic field gradient in the y-direction. The second connection unit 20b additionally comprises a second return line 22b having a cable element 23 which is electrically connected in series to the second feed line 21b. The second feed line 21b, the second gradient coil 19b, the second return line 22b, and the second power amplifier 30b typically form a closed electrical circuit.

The third connection unit 20c connects a third gradient coil 19c of the three gradient coils 19a, 19b, 19c to a third power amplifier 30c of the three power amplifiers 30a, 30b, 30c, and the third gradient coil 19c is embodied for generating a magnetic field gradient in the z-direction. The feed line 21c of the third connection unit 20c comprises precisely one cable element 23 or only cable elements electrically connected in series and is free of cable elements electrically connected in parallel. The third connection unit 20c additionally comprises a third return line 22c having a cable element 23 which is electrically connected in series to the third feed line 21c. The third feed line 21c, the third gradient coil 19c, the third return line 22c, and the third power amplifier 30c typically form a closed electrical circuit.

As shown, the first return line 22a, the second return line 22b, and/or the third return line 22c may each comprise just one cable element 23. Alternatively, the first return line 22a, the second return line 22b, and/or the third return line 22c may comprise at least two cable elements 23 at least in sections, wherein the at least two cable elements 23 per return line are electrically connected in parallel in each case.

According to the aspect shown, the system comprises a terminal unit 17 having three terminal elements 17a, 17b, 17c and three further terminal elements 18a, 18b, 18c. The terminal unit 17 is arranged at the surface of a housing enclosing the gradient coil unit 19. All the cable elements 23 of the first feed line 21a can be attached to the first gradient coil 19a via a first terminal element 17a of the three terminal elements 17a, 17b, 17c. The first return line 22a can be attached to the first gradient coil 19a via a first further terminal element 18a of the three further terminal elements 18a, 18b, 18c.

All the cable elements 23 of the second feed line 21b can be attached to the second gradient coil 19b via a second terminal element 17b of the three terminal elements 17a, 17b, 17c. The second return line 22b can be attached to the second gradient coil 19b via a second further terminal element 18b of the three further terminal elements 18a, 18b, 18c. The cable element 23 of the third feed line 21c can be attached to the third gradient coil 19c via a third terminal element 17c of the three terminal elements 17a, 17b, 17c. The third return line 22c can be attached to the third gradient coil 19c via a third further terminal element 18c of the three further terminal elements 18a, 18b, 18c.

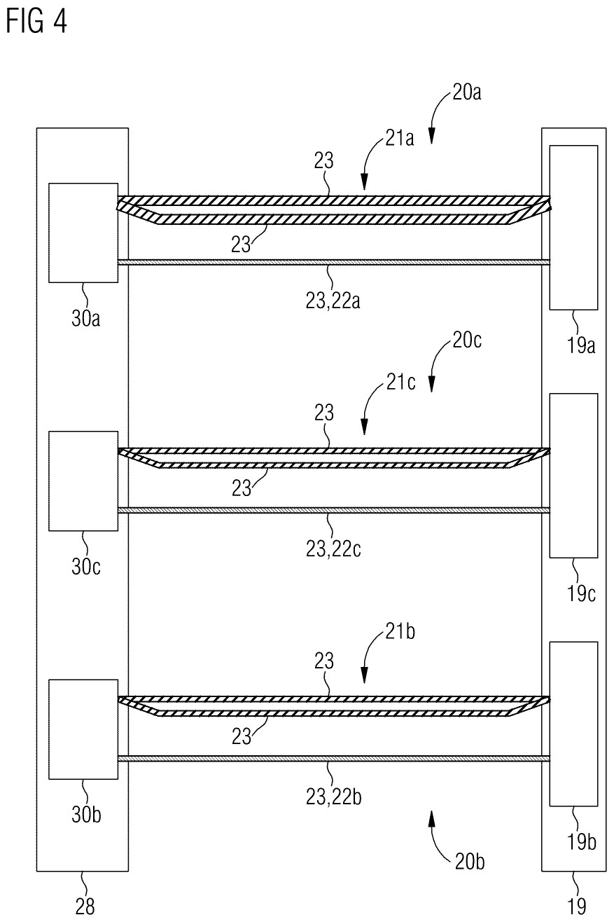

FIG. 4 shows a schematic view of a second aspect of a system according to the disclosure. The second aspect of the system is different from the first aspect shown in FIG. 3 in that the third connection unit 20c is also designed as a cable unit according to the disclosure. The cable elements 23 of the first connection unit 20a have a larger cross-sectional area than the cable elements 23 of the second connection unit 20b and/or the third connection unit 20c. For clarity of illustration reasons, the optional terminal unit 17 is not shown.

Although the disclosure has been illustrated and described in more detail on the basis of the preferred exemplary aspects, the disclosure is not limited by the disclosed examples, and other variations can be derived herefrom by the person skilled in the art without leaving the scope of protection of the disclosure. Independent of the grammatical term usage, individuals with male, female, or other gender identities are included within the term.

1. A cable unit designed to connect a gradient coil that is embodied to generate a magnetic field gradient in one spatial direction to a power amplifier, comprising at least one feed line, wherein the feed line comprises at least two cable elements at least in sections, and the at least two cable elements are connected electrically in parallel.

2. The cable unit as claimed in claim 1, wherein at least one cable element of the two cable elements has a cross-sectional area of less than 45 mm².

3. The cable unit as claimed in claim 1, further comprising a return line comprising at least one cable element, which return line is electrically connected in series to the feed line.

4. The cable unit as claimed in claim 3, wherein the feed line and the return line are embodied jointly as at least two coaxial cables which are at least partially electrically connected in parallel.

5. A system, comprising:
a gradient coil unit having three gradient coils;
a gradient control unit having three power amplifiers; and
three connection units, each connecting a gradient coil to a power amplifier and each having a feed line,
wherein the three gradient coils are in each case embodied to generate a magnetic field gradient in three different spatial directions, each feed line comprises at least one cable element in each case, and a first connection unit of the three connection units is designed as a cable unit according to claim 1.

6. The system as claimed in claim 5, wherein the first connection unit connects a first gradient coil of the three gradient coils to a first power amplifier of the three power amplifiers, and the first gradient coil is embodied to generate a magnetic field gradient in an x-direction or in a y-direction.

7. The system as claimed in claim 5, wherein at least one cable element of the feed line of the first connection unit has a larger cross-sectional area than cable elements of the feed lines of a second connection unit and/or of a third connection unit of the three connection units.

8. A system, comprising:
a gradient coil unit having three gradient coils;
a gradient control unit having three power amplifiers; and
three connection units, each connecting a gradient coil to a power amplifier and each having a feed line,
wherein the three gradient coils are in each case embodied to generate a magnetic field gradient in three different spatial directions, each feed line comprises at least one cable element in each case, and a first connection unit and a second connection unit of the three connection units are each designed as a cable unit according to claim 1.

9. A system, comprising:
a gradient coil unit having three gradient coils;
a gradient control unit having three power amplifiers; and
three connection units, each connecting a gradient coil to a power amplifier and each having a feed line,
wherein the three gradient coils are in each case embodied to generate a magnetic field gradient in three different spatial directions, each feed line comprises at least one cable element in each case, and each connection unit of the three connection units is designed as a cable unit according to claim 1.

10. The system as claimed in claim 5, wherein the feed line of a third connection unit of the three connection units comprises one cable element and is free of cable elements electrically connected in parallel.

11. The system as claimed in claim 10, wherein the third connection unit connects a third gradient coil of the three gradient coils to a third power amplifier of the three power amplifiers, and the third gradient coil is embodied for generating a magnetic field gradient in a z-direction.

12. The system as claimed in claim 5, wherein a number of cable elements of the feed lines of at least two of the three connection units are different from one another.

13. The system as claimed in claim 5, wherein cross-sections of the cable elements of the feed lines of at least two of the three connection units are different from one another.

14. The system as claimed in claim 5, wherein each connection unit of the three connection units in each case comprises a return line having at least one cable element which is electrically connected in series to the corresponding feed line.

15. The system as claimed in claim 5, further comprising:
a terminal unit arranged at a surface of a housing enclosing the gradient coil unit and having three terminal elements,
wherein, in each case, all the cable elements or the cable element of a feed line can be attached in each case to a terminal element.
